(19) United States
(12) Patent Application Publication
(10) Pub. No.: US 2023/0282508 A1
(43) Pub. Date: Sep. 7, 2023

(54) MODIFIED SEMICONDUCTOR DIE CARRIER AND CARRIER TAPE

(71) Applicant: Micron Technology, Inc., Boise, ID (US)

(72) Inventor: Po-Chun Kang, Taoyuan City (TW)

(21) Appl. No.: 18/111,424

(22) Filed: Feb. 17, 2023

Related U.S. Application Data
(60) Provisional application No. 63/315,818, filed on Mar. 2, 2022.

(51) Int. Cl. H01L 21/683

(52) U.S. Cl. CPC H01L 21/6836

(57) ABSTRACT

An apparatus for transporting a plurality of semiconductor dies comprises a first tape having a top side and a bottom side opposite of the top side, the top side including a plurality of protrusions, wherein subsets of the plurality of protrusions are grouped together and each subset is spaced apart from adjacent subsets at a predetermined interval; and a second tape having a front side and a back side opposite of the front side, the front side including a plurality of pockets, each of the plurality of pockets configured for receiving a semiconductor die, wherein each of the plurality of pockets is spaced apart from adjacent pocket at the predetermined interval. The subsets of the plurality of protrusions are configured to vertically align with the plurality of pockets.

### CROSS-REFERENCE TO RELATED APPLICATION(S)

The present application claims priority to U.S. Provisional Patent Application No. 63/315,818, filed Mar. 2, 2022, the disclosure of which is incorporated herein by reference in its entirety.

### TECHNICAL FIELD

The present disclosure relates to semiconductor die carriers, and more particularly relates to modified semiconductor die carriers and carrier tapes.

### BACKGROUND

There are numerous ways to deliver, package and transport semiconductor dies to manufacturers. Typically, semiconductor packaging methods involve protecting semiconductor dies or components by placing them in recesses of a carrier (e.g., plastic tape or container) and sealing, taping, or closing the carrier. The carriers are then packaged or boxed to ensure safe transportation with minimal damage to semiconductor dies or components during transport, delivery, and removal. One common method of packaging semiconductor dies, referred to as components in tape and reel, involves placing semiconductor dies into pockets formed in a long continuous reel and then sealing the reel, pockets, and semiconductor dies with a carrier tape. This method allows semiconductor dies to be rolled up into a reel so that manufacturers can mount the reel and feed each semiconductor die through automated PCB assembly equipment.

During the process of carrier reeling, the sealed carrier tape can experience concave bending and tape vibration causing “die shifting,” in which the semiconductor dies can shift within, or slide out of, their carrier pocket. Dies that have shifted out of their pocket can chip and/or crack during further handling, as shifted semiconductor dies receive and impart additional compressive forces. Further, during processing and removal of shifted semiconductor dies from the carrier reel by the manufacturer, feeder systems for automated assembly or testing can further damage shifted semiconductor dies by incorrect pickup of the die, or the automated assembly can run into processing errors and delays while attempting to process the shifted semiconductor dies.

### BRIEF DESCRIPTION OF THE DRAWINGS

FIG. 1 is a simplified perspective view of an exemplary sealing shoe for attaching carrier tape to carrier in accordance with an embodiment of the present disclosure.

FIGS. 2A-2L are simplified schematic cross-sectional and plan views of exemplary cover tapes attached to carrier tapes by a sealing shoe in accordance with an embodiment of the present disclosure.

FIG. 3 is a flow chart illustrating an exemplary method of making an exemplary carrier tape in accordance with an embodiment of the present disclosure.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the scope of the disclosure as defined by the appended claims.

### DETAILED DESCRIPTION

Specific details of several embodiments of semiconductor devices, carriers and carrier tapes and associated systems and methods, are described below. In this disclosure, numerous specific details are discussed to provide a thorough and enabling description for embodiments of the present disclosure. One of ordinary skill in the art will recognize that the disclosure can be practiced without one or more of the specific details. Well-known structures and/or operations often associated with semiconductor devices, sealing shoes, carriers and carrier tapes may not be shown and/or may not be described in detail to avoid obscuring other aspects of the disclosure. In general, it should be understood that various other devices, systems, and/or methods in addition to those specific embodiments disclosed herein may be within the scope of the present disclosure.

The term “semiconductor device assembly” can refer to an assembly of one or more semiconductor devices, semiconductor device packages, and/or substrates, which may include interposers, supports, and/or other suitable substrates. The semiconductor device assembly may be manufactured as, but not limited to, discrete package form, strip or matrix form, and/or wafer panel form. The term “semiconductor device” generally refers to a solid-state device that includes semiconductor material. A semiconductor device can include, for example, a semiconductor substrate, wafer, panel, or a single die from a wafer or substrate. A semiconductor device may further include one or more device layers deposited on a substrate. A semiconductor device may refer herein to a semiconductor die, but semiconductor devices are not limited to semiconductor dies.

The term “semiconductor device package” can refer to an arrangement with one or more semiconductor devices incorporated into a common package. A semiconductor package can include a housing or casing that partially or completely encapsulates at least one semiconductor device. A semiconductor package can also include a substrate that carries one or more semiconductor devices. The substrate may be attached to or otherwise incorporate within the housing or casing.

As set forth above, the process of packaging, transporting and delivering semiconductor dies on carrier reel can experience costly challenges when dies shift in or out of their pockets in a carrier tape. Embodiments of the present disclosure can address these problems and others by providing modified carrier tapes in which a cover tape includes bumps or protrusions to prevent semiconductor dies from being shifted within or displaced from their carrier tape pocket. By providing bumps or protrusions on the cover tape to prevent “die shifting” and die displacement, the foregoing difficulties caused by packaging, transport and delivery of semiconductor dies on carrier reel can be avoided and/or ameliorated, as is set forth in greater detail below.

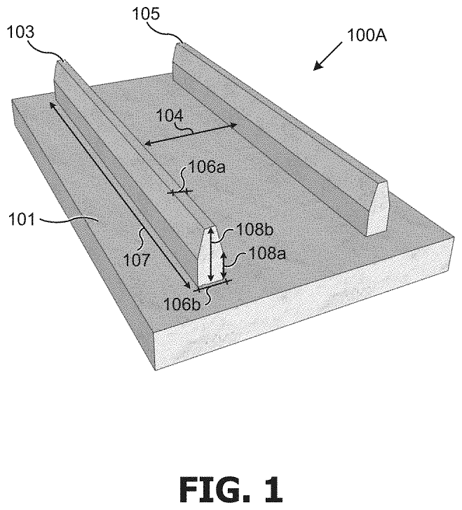

FIG. 1 is a simplified perspective view of an exemplary sealing shoe for attaching carrier tape to carrier in accordance with an embodiment of the present disclosure. As can be seen with reference to FIG. 1, an exemplary sealing shoe 100A includes a base 101 having one or more sealing blades 103, 105 for attaching, pressing and/or heat sealing a carrier tape to a carrier substrate. Since each sealing blade 103, 105 may include a heating element to heat, press and adhere the carrier tape to the carrier substrate, the spacing 104 between each sealing blade 103, 105 may be adjusted to accommodate various carrier pocket sizes and compositions, semiconductor die dimensions, and/or semiconductor die heat or pressure sensitivity. Similarly, one or more heights 108a, 108b, one or more widths 106a, 106b, and length 107 of each sealing blade 103, 105 may be adjusted as desired to accommodate various carrier pocket sizes and compositions, semiconductor die dimensions, and/or semiconductor die heat or pressure sensitivity.

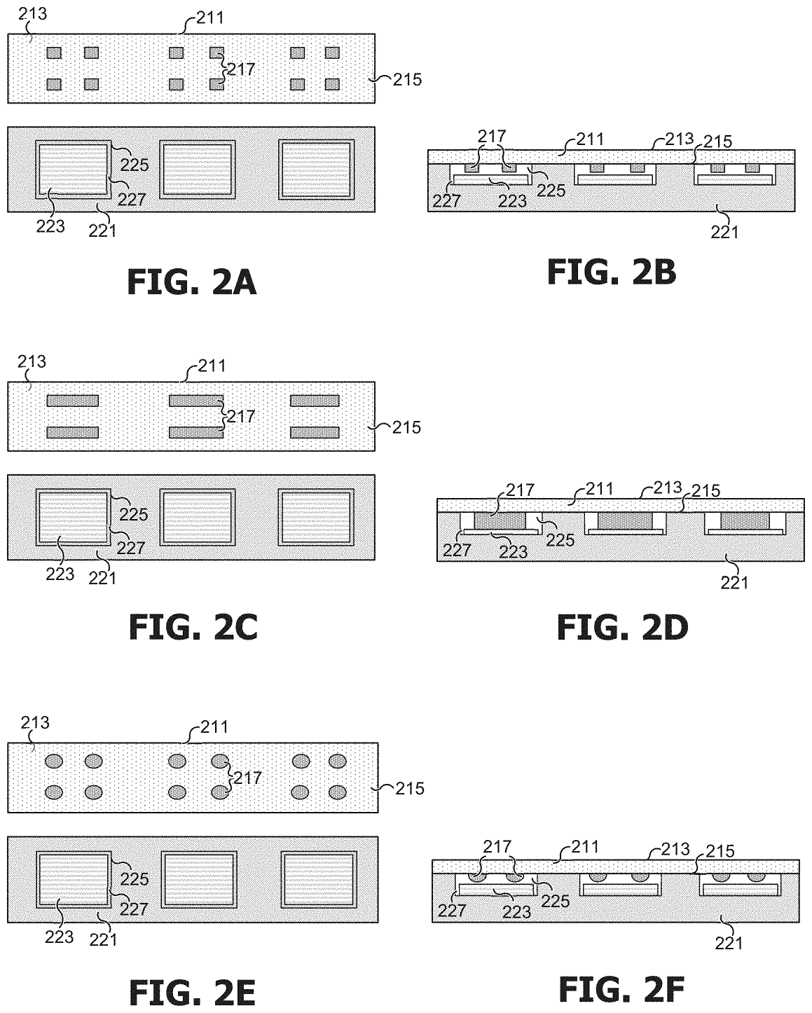

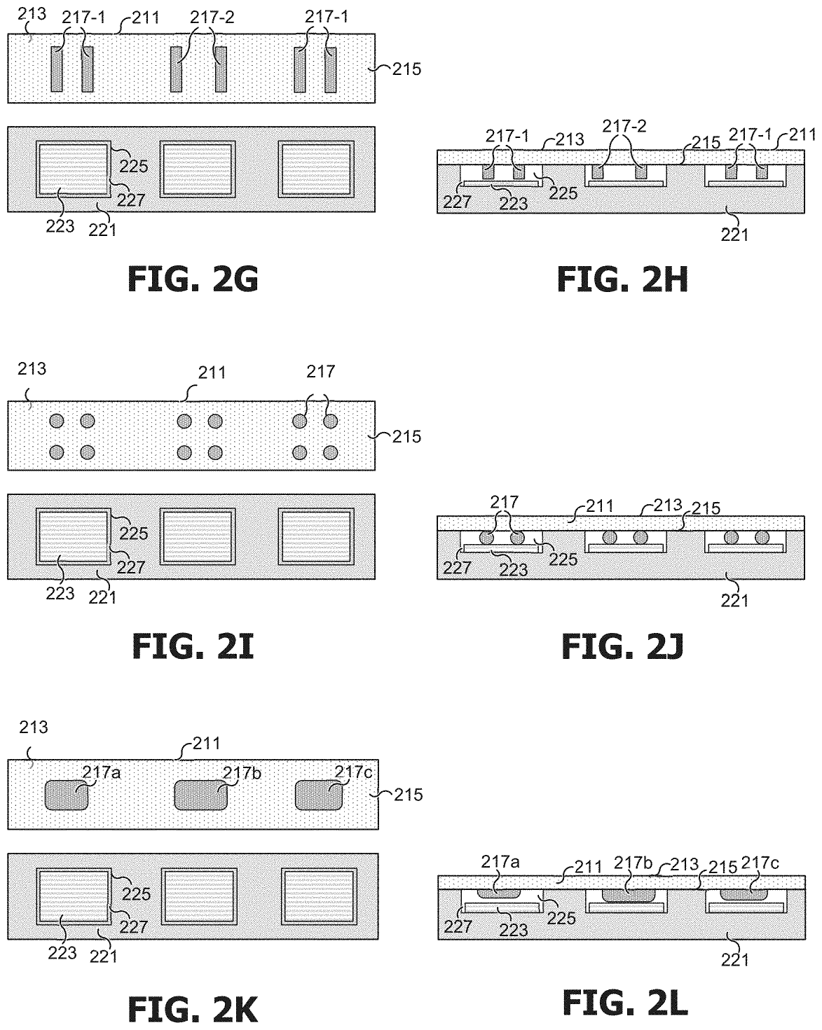

FIGS. 2A-2F are simplified schematic cross-sectional and plan views of exemplary cover tapes attached to carrier tapes by a sealing shoe in accordance with an embodiment of the present disclosure. As can be seen with reference to FIG. 2A, cover tape 211 may include one or more subsets of the plurality of protrusions 217, where each subset of the protrusions 217 may be equally spaced apart and grouped together. Moreover, each carrier pocket 225 may include a spacing 227 separating each sidewall of the semiconductor die 223 from a corresponding edge of the carrier pocket 225. In some embodiments, the subsets of protrusions 217 may be formed, deposited, or positioned on the cover tape 211 to outline the sides, curves or corners of a larger polygon, square, or other shape. Further, one or more protrusions 217 of the subset may be formed, deposited, or positioned such that adjacent edges of the protrusion 217 vertically align with adjacent sidewalls of the semiconductor die 223. In some embodiments, one or more protrusions 217 may be positioned such that adjacent edges of the protrusion 217 vertically align with adjacent edges of the carrier pocket 225, or one or more protrusions 217 may be positioned such that an edge of the protrusion 217 vertically aligns with an edge of the carrier pocket 225 and the protrusion 217 covers a portion of spacing 227, or any combination of the above.

As can be seen with reference to FIGS. 2A-2B, the exemplary cover tape 211 may be pressed and adhered to carrier tape 221 to secure semiconductor dies 223. The exemplary cover tape 211 includes a back side 213 and front side 215, the front side 215 having a plurality of protrusions 217 shaped as square bumps. The back side 213 of cover tape 211 is pressed by sealing blades 103, 105 of sealing shoe 101 to adhere the front side 215 to a surface of the carrier tape 221. The carrier tape 221 includes a plurality of carrier pockets 225, each carrier pocket 225 receiving a component or semiconductor die 223. The plurality of protrusions 217 may be grouped together and vertically aligned with and received by the carrier pocket 225. The carrier pockets 225 may be slightly larger than the semiconductor dies 223 thereby providing spacing 227 around the sidewalls of each semiconductor die 223 to allow, for example, an automated assembly equipment to easily remove the semiconductor die 223 from the carrier pocket 225 for testing or mounting to a circuit board. In some embodiments, the carrier pockets 225 may be the same size as the semiconductor dies 223. In some embodiments, the carrier pockets 225 may be slightly smaller than the semiconductor dies 223 and stretched to accommodate the semiconductor dies 223. In some embodiments, the size of spacings 227 and/or carrier pockets 225 may be increased or decreased to improve absorption of vibration or other forces by the carrier pockets 225 to prevent damage to the semiconductor dies 223.

In some embodiments, the cover tape 211 may be narrower than the carrier tape 221 such that, when adhered to the carrier tape 221, the cover tape 211 may cover opposite lengthwise edges of the carrier pockets 225 while not completely covering the top surface of the carrier tape 221. In other embodiments, the cover tape 211 may be larger than the width of the carrier tape 221 when adhered to the carrier tape 221. Moreover, the semiconductor dies 223 may be significantly thinner than the depths of carrier pockets 225 and/or significantly smaller than the length and/or width of each carrier pocket 225 leaving much larger spacings 227. In some embodiments, protrusions 217 may contact the semiconductor dies 223 to prevent die shifting. Therefore, the arrangements, dimensions, and number of protrusions 217 may be altered as desired to prevent die shifting and minimize die displacement. For example, the heights of protrusions 217 may range between 5-15 mm, semiconductor die 223 thickness may range between 20-50 mm, and carrier pocket 225 depths may range between 50-80 mm to safely accommodate semiconductor die 223 and protrusions 217 while preventing die shift and minimizing die displacement.

As can be seen with reference to FIG. 2C, cover tape 211 may include one or more subsets of the plurality of protrusions 217, where each subset of protrusions 217 may be equally spaced apart and grouped together using a common center. Moreover, each carrier pocket 225 may include a spacing 227 separating each sidewall of the semiconductor die 223 from a corresponding edge of the carrier pocket 225. In some embodiments, the subsets of protrusions 217 may be formed, deposited, or positioned on the cover tape 211 to outline the sides, curves or corners of a larger polygon, ridge, square, or other shape. Further, one or more protrusions 217 of the subset may be formed, deposited, or positioned such that adjacent edges of the protrusion 217 vertically align with adjacent sidewalls of the semiconductor die 223. In some embodiments, one or more protrusions 217 may be positioned such that adjacent edges of the protrusion 217 vertically align with adjacent edges of the carrier pocket 225, or one or more protrusions 217 may be positioned such that an edge of the protrusion 217 vertically aligns with an edge of the carrier pocket 225 and the protrusion 217 covers a portion of spacing 227, or any combination of the above.

As can be seen with reference to FIGS. 2C-2D, the exemplary cover tape 211 may be pressed and adhered to carrier tape 221 to secure thin semiconductor dies 223. The exemplary cover tape 211 includes a back side 213 and front side 215, the front side 215 having a plurality of protrusions 217 shaped as ridges. The back side 213 of cover tape 211 is pressed by sealing blades 103, 105 of sealing shoe 101 to adhere the front side 215 to a surface of the carrier tape 221. The carrier tape 221 includes a plurality of carrier pockets 225, each carrier pocket 225 receiving a component or semiconductor die 223. The plurality of protrusions 217 may be grouped together and vertically aligned with and received by the carrier pocket 225. The carrier pockets 225 are much larger than the thin semiconductor dies 223 and the carrier pockets 225 may provide spacing 227 around the sidewalls of each semiconductor die 223 to allow, for example, an automated assembly equipment to easily remove the semiconductor die 223 from the carrier pocket 225 for testing or mounting to a circuit board. In each carrier pocket 225, the protrusions 217 may extend to and contact the upper surface of the thin semiconductor dies 223 to prevent die shifting. In some embodiments, the carrier pockets 225 may be the same size as the semiconductor dies 223. In some embodiments, the carrier pockets 225 may be slightly smaller than the semiconductor dies 223 and stretched to accommodate the semiconductor dies 223. In some embodiments, the size of spacings 227 and/or carrier pockets 225 may be increased or decreased to improve absorption of vibration or other forces by the carrier pockets 225 to prevent damage to the semiconductor dies 223.

In some embodiments, the cover tape 211 may be narrower than the carrier tape 221 such that, when adhered to the carrier tape 221, the cover tape 211 may cover opposite lengthwise edges of the carrier pockets 225 while not completely covering the top surface of the carrier tape 221. In other embodiments, the cover tape 211 may be larger than the width of the carrier tape 221 when adhered to the carrier tape 221. Moreover, the semiconductor dies 223 may be significantly thinner than the depths of carrier pockets 225 and/or significantly smaller than the length and/or width of each carrier pocket 225 leaving much larger spacings 227. In some embodiments, protrusions 217 may have a very thin gap (e.g. 1-10 mm) between the semiconductor dies 223 to prevent die shifting. Further, the arrangements, dimensions, and number of protrusions 217 may be altered as desired to prevent die shifting and minimize die displacement. For example, the heights of protrusion 217 may range between 3-15 mm, semiconductor die 223 thickness may range between 20-80 mm, and carrier pocket 225 depths may range between 50-100 mm to safely accommodate semiconductor die 223 and protrusions 217 while preventing die shift and minimizing die displacement.

As can be seen with reference to FIG. 2E, cover tape 211 may include one or more subsets of the plurality of protrusions 217, where each subset of protrusions 217 may be equally spaced apart and grouped together using a common center. Moreover, each carrier pocket 225 may include a spacing 227 separating each sidewall of the semiconductor die 223 from a corresponding edge of the carrier pocket 225. In some embodiments, the subsets of protrusions 217 may be formed, deposited, or positioned on the cover tape 211 to outline the sides, curves or corners of a larger polygon, circle, square, or other shape. Further, one or more protrusions 217 of the subset may be formed, deposited, or positioned such that a surface curve of the protrusion 217 vertically aligns with adjacent sidewalls of the semiconductor die 223. In some embodiments, one or more protrusions 217 may be positioned such that a surface curve of the protrusion 217 vertically aligns with adjacent edges of the carrier pocket 225, or one or more protrusions 217 may be positioned such that a surface curve of the protrusion 217 vertically aligns with an edge of the carrier pocket 225 and the protrusion 217 covers a portion of spacing 227, or any combination of the above.

As can be seen with reference to FIGS. 2E-2F, the exemplary cover tape 211 may be pressed and adhered to carrier tape 221 to secure semiconductor dies 223. The exemplary cover tape 211 includes a back side 213 and front side 215, the front side 215 having a plurality of protrusions 217 shaped as circular bumps. The back side 213 of cover tape 211 is pressed by sealing blades 103, 105 of sealing shoe 101 to adhere the front side 215 to a surface of the carrier tape 221. The carrier tape 221 includes a plurality of carrier pockets 225, each carrier pocket 225 receiving a component or semiconductor die 223. The plurality of protrusions 217 may be grouped together and vertically aligned with and received by the carrier pocket 225. The carrier pockets 225 may be slightly larger than the semiconductor dies 223 thereby providing spacing 227 around the sidewalls of each semiconductor die 223 to allow, for example, an automated assembly equipment to easily remove the semiconductor die 223 from the carrier pocket 225 for testing or mounting to a circuit board. In some embodiments, the carrier pockets 225 may be the same size as the semiconductor dies 223. In some embodiments, the carrier pockets 225 may be slightly smaller than the semiconductor dies 223 and stretched to accommodate the semiconductor dies 223. In some embodiments, the size of spacings 227 and/or carrier pockets 225 may be increased or decreased to improve absorption of vibration or other forces by the carrier pockets 225 to prevent damage to the semiconductor dies 223.

In some embodiments, the cover tape 211 may be narrower than the carrier tape 221 such that, when adhered to the carrier tape 221, the cover tape 211 may cover opposite lengthwise edges of the carrier pockets 225 while not completely covering the top surface of the carrier tape 221. In other embodiments, the cover tape 211 may be larger than the width of the carrier tape 221 when adhered to the carrier tape 221. Moreover, the semiconductor dies 223 may be significantly thinner than the depths of carrier pockets 225 and/or significantly smaller than the length and/or width of each carrier pocket 225 leaving much larger spacings 227. In some embodiments, protrusions 217 may contact the semiconductor dies 223 to prevent die shifting. Further, the arrangements, dimensions, and number of protrusions 217 may be altered as desired to prevent die shifting and minimize die displacement. For example, the radius of protrusions 217 may range between 3-10 mm, semiconductor die 223 thickness may range between 20-80 mm, and carrier pocket 225 depths may range between 50-100 mm to safely accommodate semiconductor die 223 and protrusions 217 while preventing die shift and minimizing die displacement. The uppermost surface of the protrusion 217 may protrude from the front side 215 by a height that is equal to the radius, less than the radius, or greater than the radius of the protrusion 217. For example, the protrusion 217 may have a radius of 10 mm but protrude from the surface of the front side 215 of the cover tape 211 by a height of 2 mm. In some embodiments, the protrusion 217 may have a radius of 5 mm and protrude from the surface of the front side 215 of the cover tape 211 by a height of 7 mm. In some embodiments, the protrusion 217 may have a radius of 5 mm and protrude from the surface of the front side 215 of the cover tape 211 by a height of 5 mm.

FIGS. 2G-2L are simplified schematic cross-sectional and plan views of exemplary cover tapes attached to carrier tapes by a sealing shoe in accordance with an embodiment of the present disclosure. As can be seen with reference to FIG. 2G, cover tape 211 may include one or more subsets of the plurality of protrusions 217-1, 217-2 aligned with the carrier pocket 225, where each subset of protrusions 217-1 may be equally spaced apart and grouped together using a common center, and one or more subsets of the plurality of protrusions 217-2 where each subset of protrusions 217-2 are spaced apart and not grouped with, or like, other protrusions 217-1. Moreover, each carrier pocket 225 may include a spacing 227 separating each sidewall of the semiconductor die 223 from a corresponding edge of the carrier pocket 225. In some embodiments, the subsets of protrusions 217-1, 217-2 may be formed, deposited, or positioned on the cover tape 211 to outline the sides, curves or corners of a larger polygon, circle, square, or other shape. Further, one or more protrusions 217-1, 217-2 of the subset may be formed, deposited, or positioned such that a surface curve of the protrusion 217-1, 217-2 vertically aligns with adjacent sidewalls of the semiconductor die 223. In some embodiments, one or more protrusions 217-1, 217-2 may be positioned such that a surface curve of the protrusion 217-1, 217-2 vertically aligns with adjacent edges of the carrier pocket 225, or one or more protrusions 217-1, 217-2 may be positioned such that a surface curve of the protrusion 217-1, 217-2 vertically aligns with an edge of the carrier pocket 225 and the protrusion 217-1, 217-2 covers a portion of spacing 227, or any combination of the above. In some embodiments, one or more protrusions 217-1, 217-2 may be positioned such that an uppermost surface of the protrusions 217-1, 217-2 vertically aligns but does not contact the top surface of the carrier tape 221. In some embodiments, one or more protrusions 217-1, 217-2 may be positioned such that an uppermost surface of the protrusions 217-1, 217-2 vertically aligns and contacts the top surface of the carrier tape 221.

As can be seen with reference to FIG. 2H, the exemplary cover tape 211 may be pressed and adhered to carrier tape 221 to secure semiconductor dies 223. The exemplary cover tape 211 includes a back side 213 and front side 215, the front side 215 having a plurality of protrusions 217-1, 217-2 shaped as lateral ridges. The back side 213 of cover tape 211 is pressed by sealing blades 103, 105 of sealing shoe 101 to adhere the front side 215 to a surface of the carrier tape 221. The carrier tape 221 includes a plurality of carrier pockets 225, each carrier pocket 225 receiving a component or semiconductor die 223. The plurality of protrusions 217-1, 217-2 may include one or more protrusions 217-1 grouped together and vertically aligned with and received by the carrier pocket 225 and one or more protrusions 217-2 spread apart and not grouped together. Further, one or more protrusions 217-1, 217-2 whether grouped or spread apart may be vertically aligned with the top surface of the carrier tape 221 and outside of carrier pockets 225. The carrier pockets 225 may be slightly larger than the semiconductor dies 223 thereby providing spacing 227 around the sidewalls of each semiconductor die 223 to allow, for example, an automated assembly equipment to easily remove the semiconductor die 223 from the carrier pocket 225 for testing or mounting to a circuit board. In some embodiments, the carrier pockets 225 may be the same size as the semiconductor dies 223. In some embodiments, the carrier pockets 225 may be slightly smaller than the semiconductor dies 223 and stretched to accommodate the semiconductor dies 223. In some embodiments, the size of spacings 227 and/or carrier pockets 225 may be increased or decreased to improve absorption of vibration or other forces by the carrier pockets 225 to prevent damage to the semiconductor dies 223.

As can be seen with reference to FIGS. 21-2J, the cover tape 211 may include a matrix of protrusions 217 shaped as circular bumps equally spaced apart and arranged across the front side 215 of cover tape 211 where one or more protrusions 217 in the matrix are vertically aligned with and received by the carrier pocket 225. In some embodiments, one or more protrusions 217 are vertically aligned with the top surface of the carrier tape 221 and received by an upper surface of the carrier tape 221 outside of carrier pockets 225. Moreover, one or more protrusions 217 may be positioned such that an uppermost surface of the protrusion 217 vertically aligns but does not contact the top surface of the carrier tape 221 and/or one or more protrusions 217 may be positioned such that an uppermost surface of the protrusions 217 vertically aligns and contacts the top surface of the carrier tape 221.

As can be seen with reference to FIGS. 2K-2L, there may be variability in arrangement, alignment, size, thickness, shape, and curvature of any of the above exemplary protrusions 217 as desired to ensure semiconductor dies are not damaged by, for example, preventing die shifting and minimizing die displacement. For example, each of the plurality of protrusions 217a, 217b, 217c, 217, 217-1, or 217-2, may be spaced, shaped, sized or formed differently from neighboring or adjacent protrusions.

In some embodiments, the cover tape 211 may be narrower than the carrier tape 221 such that, when adhered to the carrier tape 221, the cover tape 211 may cover opposite lengthwise edges of the carrier pockets 225 while not completely covering the top surface of the carrier tape 221. In other embodiments, the cover tape 211 may be larger than the width of the carrier tape 221 when adhered to the carrier tape 221. Moreover, the semiconductor dies 223 may be significantly thinner than the depths of carrier pockets 225 and/or significantly smaller than the length and/or width of each carrier pocket 225 leaving much larger spacings 227. In some embodiments, protrusions 217 may contact the semiconductor dies 223 to prevent die shifting. Therefore, the arrangements, dimensions, and number of protrusions 217 may be altered as desired to prevent die shifting and minimize die displacement. For example, the radius of protrusion 217 may range between 3-10 mm, semiconductor die 223 thickness may range between 20-80 mm, and carrier pocket 225 depths may range between 50-100 mm to safely accommodate semiconductor die 223 and protrusions 217 while preventing die shift and minimizing die displacement. The uppermost surface of the protrusion 217 may protrude from the front side 215 by a height that is equal to the radius, less than the radius, or greater than the radius of the protrusion 217. For example, the protrusion 217 may have a radius of 10 mm but protrude from the surface of the front side 215 of the cover tape 211 by a height of 2 mm. In some embodiments, the protrusion 217 may have a radius of 5 mm and protrude from the surface of the front side 215 of the cover tape 211 by a height of 7 mm. In some embodiments, the protrusion 217 may have a radius of 5 mm and protrude from the surface of the front side 215 of the cover tape 211 by a height of 5 mm.

Any of the protrusions 217 (square bumps, ridges, circular bumps, elliptical bumps, etc.) described in the present disclosure may include one or more protrusions grouped together and vertically aligned with and received by the carrier pocket 225 and one or more protrusions spread apart and not grouped together. Further, one or more protrusions whether grouped or spread apart may be vertically aligned with the top surface of the carrier tape 221 and outside of carrier pockets 225. Moreover, one or more protrusions may be positioned such that an uppermost surface of the protrusion vertically aligns but does not contact the top surface of the carrier tape 221 and/or one or more protrusions may be positioned such that an uppermost surface of the protrusions vertically aligns and contacts the top surface of the carrier tape 221.

Any of the spacings 227 described in the present disclosure may be empty (e.g. a vacuum) or filled with a noble or inert gas or air. In some embodiments, the spacing 227 may further contain other elements or particulates used in the manufacture of the semiconductor devices or carrier substrates, for example, polyester and/or polycarbonate materials, thermoplastic polymers, oxides, nitrides, carbides, plastics and polymers. Moreover, each spacing 227 may be filled with one or more gases, materials (e.g. elements or particulates), or any mixture of gases or materials presented above.

Examples of material which could be used in the formation of the protrusions 217 (square bumps, ridges, circular bumps, elliptical bumps, etc.) may include, for example, polyester and/or polycarbonate materials, thermoplastic polymers, oxides, nitrides, carbides, plastics and polymers, epoxy, or any combination thereof. Any convenient deposition method may be used, including spin coating, chemical vapor deposition (CVD), atomic layer deposition (ALD), vapor deposition polymerization (VDP), or physical vapor deposition (PVD).

The protrusions 217 (e.g., square bumps, ridges, circular bumps, elliptical bumps, etc.) may be formed by deposition of any of the above materials onto the front side 215 of the cover tape 211. In some embodiments, protrusions may be formed by introducing a compressive force to the back side 213 of cover tape 211, for example, a stamper or stamping mechanism may be applied to the back side 213 of cover tape 211 to form each of the protrusions on the front side 215. In some exemplary embodiments, the applied compressive force to back side 213 of cover tape 211 may deform one or more portions of the carrier tape thereby forming one, several, or all of a plurality of protrusions that may take any of the above shapes or each of the (deformed) plurality of protrusions may be subsequently shaped into a square, ridge, circular or elliptical bump, etc. In some exemplary embodiments, the protrusions may be formed in a separate process and attached to the front side 215 of the cover tape 211 by an adhesive.

The carrier pockets 225 may be recesses in the carrier tape 221 having substantially sharp or rigid corners, pockets in the carrier tape 221 having more curved corners or sidewalls, or cavities in the carrier tape 221 having rough or uneven sidewalls or corners, or a combination of the above.

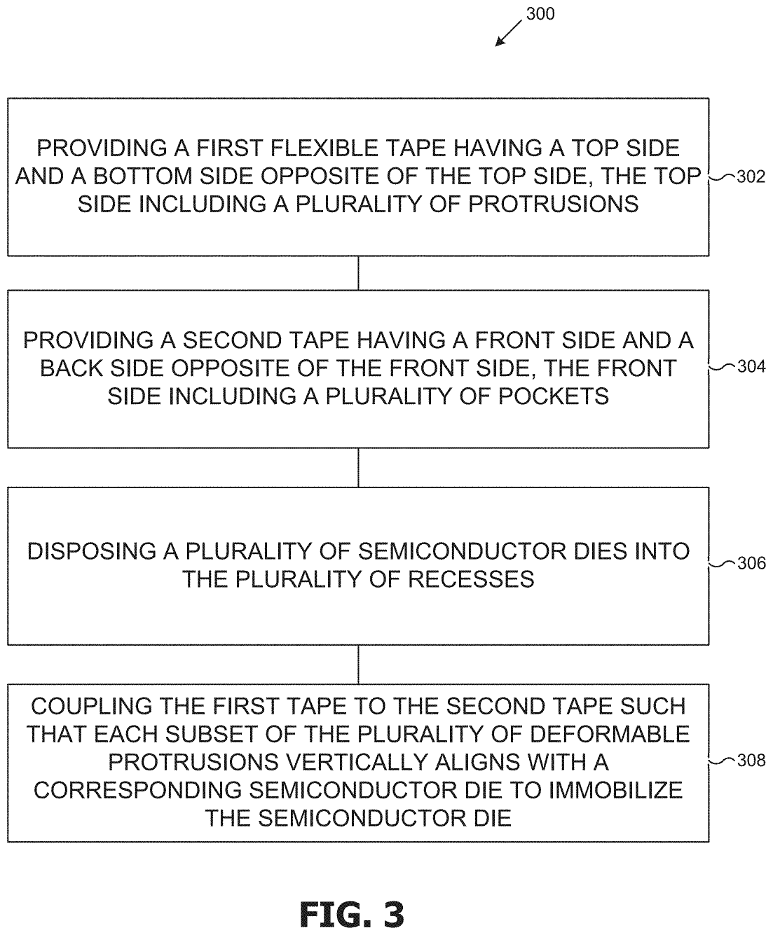

FIG. 3 is a flow chart illustrating an exemplary method of making an apparatus for transporting a plurality of semiconductor dies. The exemplary method is provided by way of example, as there are a variety of ways to carry out the method. Each box shown in FIG. 3 represents one or more processes, methods or subroutines, carried out in the exemplary method. FIGS. 1 and 2A-2L show exemplary embodiments of carrying out the method of FIG. 3. The exemplary method may begin at box 302. Further for explanatory purposes, the boxes of the example process 300 are described herein as occurring in serial, or linearly. However, multiple boxes of the example process 300 may occur in parallel. In addition, the boxes of the example process 300 may be performed a different order than the order shown and/or one or more of the boxes of the example process 300 may not be performed.

The exemplary method of FIG. 3 includes providing a first flexible tape having a top side and a bottom side opposite of the top side, the top side including a plurality of protrusions (box 302). According to one aspect of the present disclosure, subsets of the plurality of protrusions are grouped together and each subset is spaced apart from adjacent subsets at a predetermined interval. The method further includes providing a second tape having a front side and a back side opposite of the front side, the front side including a plurality of pockets (box 304). According to one aspect of the present disclosure, each of the plurality of pockets is configured for receiving a semiconductor die, and is spaced apart from adjacent pockets at the predetermined interval. The method further includes disposing a plurality of semiconductor dies into the plurality of recesses (box 306). The method further includes coupling the first tape to the second tape such that each subset of the plurality of deformable protrusions vertically aligns with a corresponding semiconductor die to immobilize the semiconductor die (box 308). In some exemplary embodiments, exterior surfaces of each of the plurality of protrusions are spaced apart from sidewalls of each of the plurality of recesses in the second flexible tape, and each subset of the plurality of protrusions vertically aligns with each semiconductor die to immobilize the semiconductor die.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” may refer to relative directions or positions of features in the semiconductor devices in view of the orientation shown in the Figures. For example, “upper” or “uppermost” may refer to a feature positioned closer to the top of a page than another feature. These terms, however, should be construed broadly to include semiconductor devices having other orientations, such as inverted or inclined orientations where top/bottom, over/under, above/below, up/down, and left/right may be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the present disclosure have been described herein for purposes of illustration, but that various modifications may be made without deviating from the scope of the present disclosure. Rather, in the foregoing description, numerous specific details are discussed to provide a thorough and enabling description for embodiments of the present disclosure. One skilled in the relevant art, however, will recognize that the disclosure may be practiced without one or more of the specific details. In other instances, well-known structures or operations often associated with memory systems and devices are not shown, or are not described in detail, to avoid obscuring other aspects of the present disclosure. In general, it should be understood that various other devices, systems, and methods in addition to those specific embodiments disclosed herein may be within the scope of the present disclosure.

What is claimed:

1. An apparatus for transporting a plurality of semiconductor dies, comprising:
a first flexible tape having a top side and a bottom side opposite of the top side, the top side including a plurality of deformable protrusions, wherein subsets of the plurality of deformable protrusions are grouped together and each subset is spaced apart from adjacent subsets at a predetermined interval;
a second flexible tape having a front side and a back side opposite of the front side, the front side including:
a plurality of recesses, each of the plurality of recesses configured for receiving a corresponding one of the plurality of semiconductor dies,
wherein each of the plurality of recesses is spaced apart from adjacent recesses at the predetermined interval, and
the plurality of semiconductor dies, each of the plurality of semiconductor dies disposed within a corresponding one of the plurality of recesses;
wherein each subset of the plurality of deformable protrusions vertically aligns with a corresponding semiconductor die to immobilize the semiconductor die; and
wherein at least a portion of the top side of the first flexible tape is coupled to the front side of the second flexible tape.

2. The apparatus of claim 1, wherein portions of the first flexible tape are deformed and the deformed portions of the first flexible tape form the plurality of deformable protrusions.

3. The apparatus of claim 1, wherein each of the plurality of deformable protrusions comprise substantially circular bumps.

4. The apparatus of claim 1, wherein each of the plurality of deformable protrusions forms ridges extending longitudinally or laterally along the top side of the first flexible tape.

5. The apparatus of claim 1, wherein each of the plurality of protrusions are attached to the top side of the first tape by an adhesive.

6. The apparatus of claim 1, wherein a depth of each of the plurality of recesses is greater than a thickness of each of the plurality of deformable protrusions.

7. The apparatus of claim 1, wherein an exterior surface of each of the plurality of deformable protrusions contacts an upper surface of the corresponding semiconductor die.

8. The apparatus of claim 1, wherein exterior surfaces of each of the plurality of deformable protrusions are spaced apart from sidewalls of each of the plurality of recesses in the second flexible tape.

9. An apparatus for transporting a plurality of semiconductor dies, comprising:
a first tape having a top side and a bottom side opposite of the top side, the top side including a plurality of protrusions, wherein subsets of the plurality of protrusions are grouped together and each subset is spaced apart from adjacent subsets at a predetermined interval; and
a second tape having a front side and a back side opposite of the front side, the front side including a plurality of pockets, each of the plurality of pockets configured for receiving a semiconductor die, wherein each of the plurality of pockets is spaced apart from adjacent pocket at the predetermined interval;
wherein the subsets of the plurality of protrusions are configured to vertically align with the plurality of pockets.

10. The apparatus of claim 9, wherein one or more portions of the first tape are deformed to form at least one of the plurality of protrusions.

11. The apparatus of claim 9, wherein each of the plurality of protrusions forms a substantially circular bump.

12. The apparatus of claim 9, wherein each of the plurality of protrusions forms a ridge extending laterally or longitudinally along the top side of the first tape.

13. The apparatus of claim 9, wherein each of the plurality of protrusions are attached to the top side of the first tape by an adhesive.

14. The apparatus of claim 9, wherein each of the plurality of protrusions is transparent.

15. The apparatus of claim 9, wherein a depth of each of the plurality of recesses is greater than a thickness of each of the plurality of deformable protrusions.

16. A method of transporting a plurality of semiconductor dies, comprising:
providing a first flexible tape having a top side and a bottom side opposite of the top side, the top side including a plurality of protrusions, wherein subsets of the plurality of protrusions are grouped together and each subset is spaced apart from adjacent subsets at a predetermined interval;
providing a second tape having a front side and a back side opposite of the front side, the front side including a plurality of pockets, each of the plurality of pockets configured for receiving a semiconductor die, wherein each of the plurality of pockets is spaced apart from adjacent pockets at the predetermined interval;
disposing a plurality of semiconductor dies into the plurality of recesses; and
coupling the first tape to the second tape such that each subset of the plurality of deformable protrusions vertically aligns with a corresponding semiconductor die to immobilize the semiconductor die.

17. The method of claim 16, wherein each of the formed plurality of deformable protrusions is further shaped by introducing a compressive force to each of the plurality of deformable protrusions.

18. The method of claim 16, wherein each of the plurality of deformable protrusions comprise bumps that are substantially circular in shape.

19. The method of claim 16, wherein a depth of each of the plurality of recesses in the second flexible tape is greater than a thickness of each of the plurality of deformable protrusions.

20. The method of claim 16, wherein exterior surfaces of each of the plurality of deformable protrusions are spaced apart from sidewalls of each of the plurality of recesses in the second flexible tape.
